(19) United States
(12) Patent Application Publication
(10) Pub. No.: US 2002/0056415 A1
(43) Pub. Date: May 16, 2002

(54) Apparatus and method for production of solar cells

(75) Inventors: Satoshi Mashima, Senboku-gun (JP); Katsuhiko Nomoto, Kashiwara-shi (JP)

Correspondence Address: NIXON & VANDERHYE P.C., 8th Floor, 1100 North Glebe Road, Arlington, VA, 22201, US

(73) Assignee: Sharp Kabushiki Kaisha

(21) Appl. No.: 09/997,244

(22) Filed: Nov. 30, 2001

Related U.S. Application Data
(63) Continuation-in-part of application No. 09/492,109, filed on Jan. 27, 2000, now abandoned.

(30) Foreign Application Priority Data
Jan. 29, 1999 (JP) HE11(1999)-022274

(51) Int. Cl. C23C 16/00

(52) U.S. Cl. 118/723 E

(57) ABSTRACT

A solar cell production method includes the steps of: forming a first electrode layer on a substrate, sequentially forming a p-layer, an i-layer and an n-layer of amorphous silicon on the first electrode layer, and forming a second electrode layer on the n-layer, wherein the i-layer is formed by a plasma CVD method employing plasma discharge caused by application of a pulse-modulated high frequency voltage having a pulse ON time of not longer than 50 μ sec and a duty ratio of not higher than 50% to improve a photo-electric conversion efficiency of the solar cell.

### CROSS-REFERENCE TO RELATED APPLICATION

This application is a continuation-in-part of U.S. patent application Ser. No. 09/492,109 filed on Jan. 27, 2000, the disclosure of which is incorporated by reference in its entirety.

### BACKGROUND OF THE INVENTION

1. Field of the Invention

The present invention relates to an apparatus and a method for production of electronic devices and, more particularly, to an apparatus and a method for production of electronic devices, which are suitable, in the electronic industry, for a plasma excited chemical vapor deposition apparatus (hereinafter referred to as “plasma CVD apparatus”) for forming a semiconductor film or an insulating film such as of hydrogenated amorphous silicon (hereinafter referred to as “a-Si:H”), or for a plasma etching device for processing a semiconductor device or a liquid crystal device.

2. Description of the Related Art

Plasma CVD apparatuses for deposition of a thin film in a gaseous atmosphere produced by plasma excitation and decomposition of a material gas and plasma etching apparatuses for processing a semiconductor device or a liquid crystal display device are widely used for production of electronic devices which involves processing of a metal film, a semiconductor film and/or a dielectric film, or a crystalline wafer.

In order to achieve a higher through-put (productivity) in these production apparatuses, it is particularly important to process a multiplicity of substrates at a time. To this end, the size of a reaction chamber, the sizes of cathode and anode electrodes and the numbers of the cathode and anode electrodes are increased.

It is also important to increase the processing speeds of the apparatuses for a higher through-put. One known approach to the increase of the processing speed for film deposition is to employ a high-speed and high-quality a-Si:H film deposition technique by a short-pulse VHF plasma CVD method (see, for example, Japanese Unexamined Patent Publication No. Hei 7(1995)-166358).

The processing speed of a plasma CVD apparatus may be increased by increasing an electric power, a frequency or the like for the plasma discharge. If the processing speed exceeds a certain level, however, abnormal discharge phenomena such as production of particles (powder) and occurrence of discharge in an unintended space (other than a space where a substrate to be processed is placed) are liable to take place, making it impossible to carry out a desired process.

It has been known that pulse-modulated discharge is effective for suppression of the production of the particles (Y. Watanabe, et al., Appl. Phys. Lett., 57. 1616 (1990)).

The level of the electric power at which the abnormal discharge starts occurring depends upon the discharge frequency, the size of electrodes and the like which are employed for the discharge. For a higher through-put, it is necessary to process a multiplicity of substrates at a time, i.e., to increase the number of electrodes.

Where a high frequency power is applied to a plurality of electrodes placed in a single space (in a vacuum vessel), however, plasma interference occurs, so that the abnormal discharge phenomena are liable to occur. This results in a reduction in processing speed per electrode as compared with a case where a single electrode is employed.

### SUMMARY OF THE INVENTION

In view of the foregoing, the present invention is directed to providing a production apparatus and a production method, which prevent the reduction in processing speed per-electrode when a plurality of electrodes are employed for processing a plurality of substrates, thereby drastically improving the mass-productivity of electronic devices such as solar batteries and liquid crystal display devices which utilize a-Si:H thin films in the electronic industry.

In accordance with one aspect of the present invention, there is provided an apparatus for production of electronic devices, which comprises: a vacuum vessel having first and second pairs of opposed electrodes provided therein; a gas inlet for introducing a material gas into the vacuum vessel; and first and second power sources for applying first and second high frequency voltages between the first pair of electrodes and between the second pair of electrodes, respectively, to cause plasma discharge, the first and second high frequency voltages being modulated in accordance with first and second pulse waves, respectively; wherein ON periods of the first and second pulse waves are controlled so as not to coincide with each other.

In accordance with another aspect of the present invention, there is provided a solar cell production method, which comprises the steps of: forming a first electrode layer on a substrate; sequentially forming a p-layer, an i-layer and an n-layer of amorphous silicon on the first electrode layer; and forming a second electrode layer on the n-layer; wherein the i-layer is formed by a plasma CVD method employing plasma discharge caused by application of a pulse-modulated high frequency voltage having a pulse ON time of not longer than 50 μsec and a duty ratio of not higher than 50%.

### BRIEF DESCRIPTION OF THE DRAWINGS

FIG. 1 is a diagram illustrating the construction of an electronic device production apparatus which is applied to a plasma CVD apparatus in accordance with an embodiment of the present invention; and

FIG. 2 is a timing chart showing modulating pulse waveforms in accordance with the embodiment of the present invention.

FIG. 3 is a diagram illustrating the construction of a solar cell produced by a method according to the present invention;

FIG. 4 is a graph illustrating the photo-electric conversion efficiency characteristic of the solar cell produced by the inventive method; and

FIG. 5 is a graph illustrating the hydrogen content of an amorphous silicon layer of the solar cell produced by the inventive method.

### DETAILED DESCRIPTION OF THE INVENTION

In the present invention, the expression “first and second pairs of opposed electrodes” means at least two pairs of opposed electrodes, so that three or more pairs of opposed electrodes may be employed. The opposed electrodes are, for example, electrode plates opposed to each other in a parallel relation.

A component, such as a wafer, to be processed is placed on one of the opposed electrodes in each pair. The one electrode on which the component is to be placed is generally referred to as a cathode electrode, which is grounded. The other electrode is referred to as an anode electrode.

In the present invention, the vacuum vessel is designed so that the material gas introduced therein can be maintained at a pressure level of about 10⁻¹ torr to about 1 torr.

Where the inventive apparatus is employed as a plasma CVD apparatus for formation of a-Si:H films, SiH₄, Si₂H₆, a gas mixture containing SiH₄ or Si₂H₆ and any of CH₄, C₂H₆, PH₃, B₂H₆ and GeH₄, or a gas mixture containing any of H₂, He, Ar, Xe and Kr diluted with SiH₄ or Si₂H₆, for example, is used as the material gas. For formation of an Si oxide film, an SiH₄—N₂O gas, for example, is used as the material gas.

Where the inventive apparatus is employed as a plasma etching apparatus, CF₄, CF₃, Cl, CF₂, Cl₂, CFCl₃, CF₃BR or CCl₄ is used as a reaction gas for processing of an Si-based component, and CF₄, C₂F₆, C₃F₈ or CHF₃ is used as a reaction gas for processing of an SiO₂-based component.

In the present-invention, the gas inlet is adapted to supply the gas into the vacuum vessel, for example, from a gas cylinder. The first and second power sources are adapted to output pulse-modulated high frequency voltages to cause plasma discharge between the first pair of electrodes and between the second pair of electrodes, respectively. The high frequency outputs of the first and second power sources preferably have the same frequency, but may have different frequencies.

The frequency of the high frequency voltage may be in a frequency band between a radio frequency and a ultra high frequency, for example, including a radio frequency of 13.56 MHz, a very high frequency (VHF on the order of several tens MHz) and a ultra high frequency (UHF on the order of several hundreds MHz).

The first and second power sources are adapted to pulse-modulate the high frequency voltages in accordance, with first and second pulse waves, respectively, and apply the pulse-modulated voltages between the respective pairs of electrodes. At this time, the ON periods of the modulating pulse waves are controlled by the first and second power-sources so as not to coincide with each other. This prevents the plasma discharge interference between the first pair of electrodes and the second pair of electrodes even if the power for the plasma discharge is increased. Accordingly, the abnormal discharge can be prevented.

The ON periods of the modulating pulse waves may be from 1 μs to 100 μs, and the OFF periods of the pulse waves may be from 5 μs to 500 μs. A duty ratio of not greater than 20% for the modulating pulse waves further effectively prevents the abnormal discharge.

The present invention will hereinafter be described in detail by way of an illustrated embodiment.

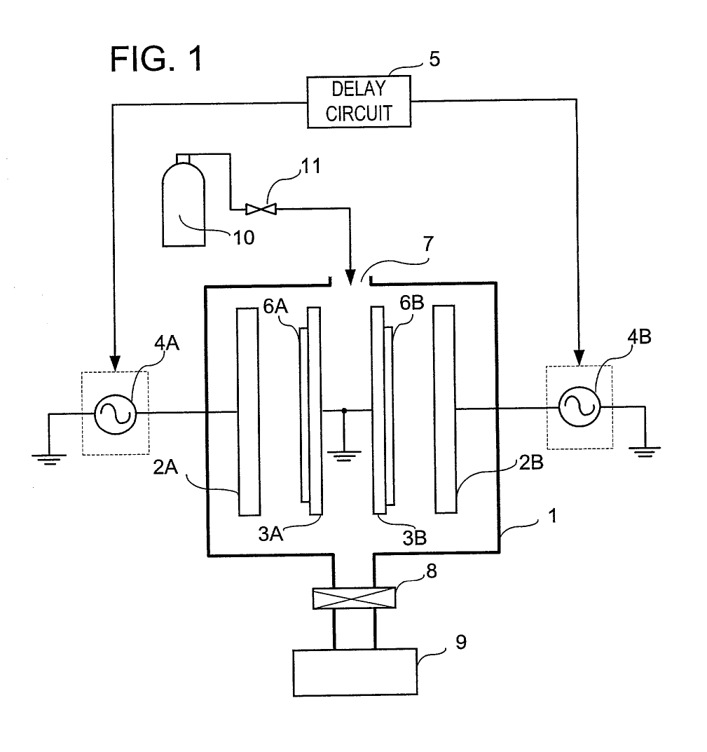

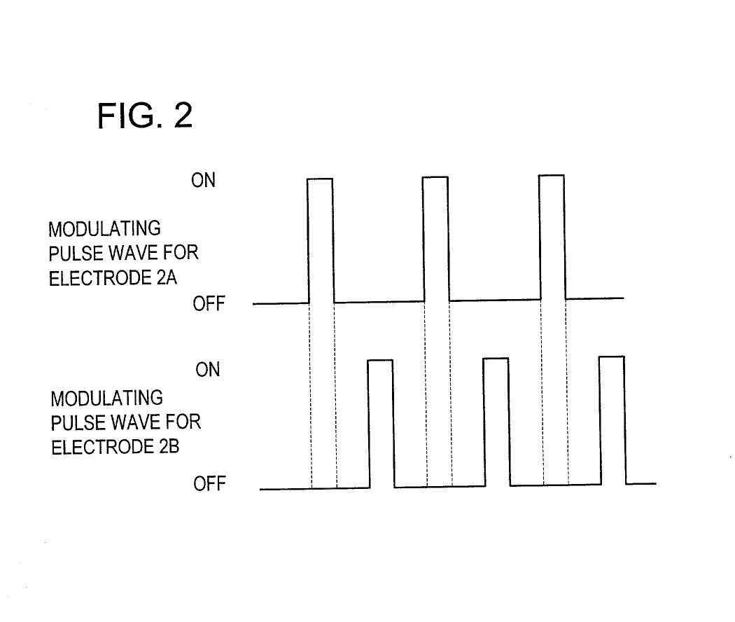

FIG. 1 is a diagram illustrating the construction of an electronic device production apparatus, and FIG. 2 is a timing chart of modulating pulse waves for modulating the high frequency voltages applied between respective pairs of electrodes in the apparatus. The electronic device production apparatus is herein used as a plasma CVD apparatus.

As shown in FIG. 1, two anode electrodes 2A and 2B and two cathode electrodes 3A and 3B are disposed in a parallel relation within a vacuum vessel 1. Substrates to be processed (components to be processed) 6A and 6B are placed on the cathode electrodes 3A and 3B, respectively. The cathode electrodes 3A, 3B are electrically grounded to the vacuum vessel 1, and therefore their potentials are at a ground level.

A gas inlet 7 is provided at the top of the vacuum vessel 1, and a material gas is introduced into the vacuum vessel 1 from a gas cylinder 10 through a valve 11 and the gas inlet 7. The gas introduced into the vacuum vessel 1 is drawn out via a main valve 8 by a vacuum pump 9.

Pulse-modulated high frequency power generators 4A and 4B are connected to the anode electrodes 2A and 2B, respectively, via lines extending through central portions of right and left walls of the vacuum vessel 1. By a pulse signal delay circuit 5, the ON periods of modulating pulse waves for modulating the high frequency voltages applied to the respective anode electrodes 2A, 2B are controlled so as not to coincide with each other.

The vacuum vessel 1 has a sectional area of 1.6 m×1.6 m as measured parallel to the surfaces of the electrodes. The anode electrodes 2A, 2B and the cathode electrodes 3A, 3B each have a size of 700 mm×700 mm.

A gas mixture of silane and hydrogen is used as the material gas. Discharge parameters to be employed include a frequency of 27.12 MHz, an ON period of the modulating pulse waves of 10 μsec, and a duty ratio of 20%.

Under such conditions, plasma discharge is allowed to occur between the electrodes 2A and 3A and between the electrodes 2B and 3B with the material gas being introduced into the vacuum vessel 1 to form a-Si:H films on the respective substrates 6A and 6B. In an experiment, when the ON periods of the modulating pulse waves for modulating the high frequency voltages applied to the anode electrodes 2A and 2B are allowed to coincide with each other, abnormal discharge occurred at a discharge power of 500 W.

When the ON periods of the pulse waves are offset from each other by 25 μsec, normal discharge (between the anode electrodes and the cathode electrodes) is ensured at a discharge power up to 950 W. Therefore, the apparatus allows for high speed film formation even when two substrates are simultaneously processed, thereby improving the mass-productivity.

Although an explanation has been given to a case where the electronic device production apparatus is applied to the plasma CVD apparatus in this embodiment, the electronic device production apparatus is applicable to a plasma dry etching apparatus for etching a film with species activated by plasma particles and plasma excitation, and provides for the same effects.

Where the electronic device production apparatus according to the present invention is applied to a plasma CVD apparatus for processing a plurality of substrates with the use of plural pairs of electrodes, the reduction in the processing speed per electrode pair can be prevented, thereby improving the mass-productivity of electronic devices such as solar batteries and liquid crystal display devices which utilize a-Si:H thin films in the electronic industry.

Where the electronic device production apparatus according to the present invention is applied to a plasma etching apparatus for etching a film with species activated by plasma particles and plasma excitation, the mass-productivity of electronic devices such as liquid crystal display devices can be improved.

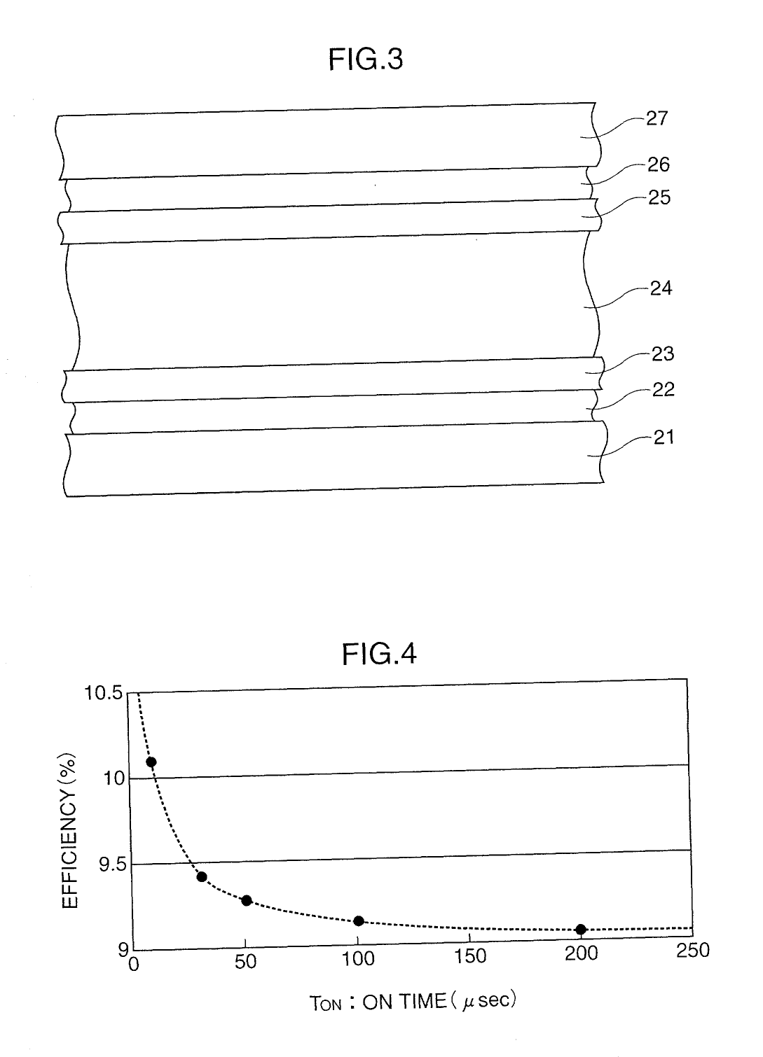

A solar cell production method employing the plasma CVD apparatus shown in FIG. 1 will hereinafter be described with reference to FIG. 3.

(1) An 800-nm thick SnO₂ transparent electrode 22 is formed on a 4-mm thick glass substrate 21 by an atmospheric pressure CVD method.

(2) With the use of an ordinary plasma CVD apparatus, a 12-nm thick a-SiC layer 23 is formed as a p-layer on the transparent electrode 22.

(3) With the use of the plasma CVD apparatus shown in FIG. 1, a 300-nm thick a-Si layer 24 is formed as an i-layer in accordance with the following steps (a) to (c).

(a) Two substrates 6A, 6B each prepared in accordance with the aforesaid steps (1) and (2) are respectively attached to the cathodes 3A, 3B, and then heated at 200° C. by heaters incorporated in the cathodes 3A, 3B.

(b) The inside pressure of the vessel 1 is kept at 0.3 Torr, and SiH₄ gas and H₂ gas are introduced into the vessel 1 at flow rates of 600 sccm and 200 sccm, respectively.

(c) At the same time, a 27.12-MHz high frequency voltage which is pulse-modulated so as to have a pulse ON time T_{ON} of 5 sec and a pulse OFF time T_{OFF} of 50 μsec (duty ratio=20%) is alternately applied between the electrode 2A and the substrate 6A and between the electrode 2B and the substrate 6B as shown in FIG. 2 to cause plasma discharge. The power is supplied at 3 kW.

(4) With the use of another ordinary plasma CVD apparatus, a 30-nm thick a-Si layer is formed as an n-layer on each of the substrates obtained in the step (3).

(5) A 50-nm thick ZnO transparent electrode 26 and a 300-nm thick Ag rear electrode 27 are formed on each of the resulting substrates by a sputtering method. Thus, two solar cells are simultaneously produced.

A relationship between the photo-electric conversion efficiency of the solar cells thus produced and the pulse ON time T_{ON} in the step (3)-(c) of the method according to the present invention was experimentally determined, and the results are shown in FIG. 4. It is noted that the pulse OFF time T_{OFF} was constant at 50 μsec in the experiment.

As can be understood from FIG. 4, a pulse ON time of T_{ON}≦50 μsec (duty ratio≦50%) provides an improved photo-electric conversion efficiency, and a pulse ON time of T_{ON}≦10 μsec (duty ratio≦20%) provides a further improved photo-electric conversion efficiency as compared with a pulse ON time of T_{ON}≧150 μsec.

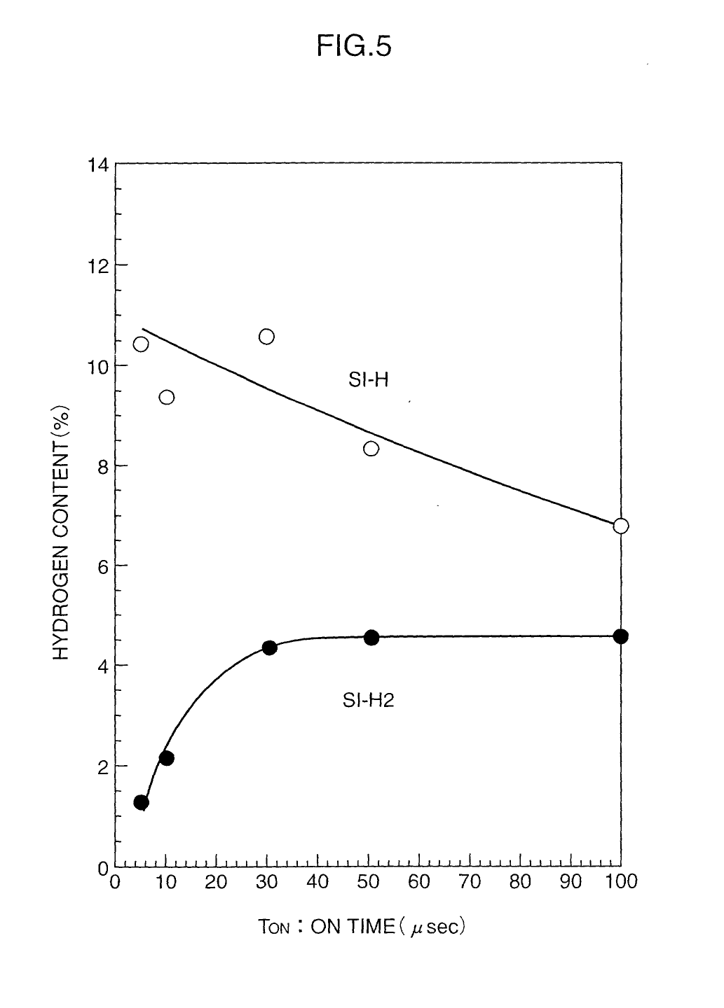

In connection with the experiment shown in FIG. 4, a relationship between the pulse ON time T_{ON} and the hydrogen content of the a-Si layer 24 was experimentally determined, and the results are shown in FIG. 5. As can be understood from FIG. 5, a reduction in the number of Si-H₂ bonds starts when the pulse ON time is T_{ON}=50 μsec, and is more remarkable when the pulse ON time is T_{ON}10 μsec. Therefore, the characteristics shown in FIG. 5 are correlated with the results shown in FIG. 4.

What is claimed is:

1. A solar cell production method comprising the steps of:
forming a first electrode layer on a substrate,
sequentially forming a p-layer, an i-layer and an n-layer of amorphous silicon on the first electrode layer, and
forming a second electrode layer on the n-layer,
wherein the i-layer is formed by a plasma CVD method employing plasma discharge caused by application of a pulse-modulated high frequency voltage having a pulse ON time of not longer than 50 μsec and a duty ratio of not higher than 50% to improve a photo-electric conversion efficiency of the solar cell.

2. A solar cell production method as set forth in claim 1, wherein the pulse ON time is not longer than 10 μsec and the duty ratio is not higher than 20%.

3. An electronic device production apparatus to be employed for a production method as recited in claim 1, the apparatus comprising:
a vacuum vessel having first and second pairs of opposed electrodes provided therein,
a gas inlet for introducing a material gas into the vacuum vessel, and
first and second power sources for applying pulse-modulated high frequency voltages between the first pair of electrodes and between the second pair of electrodes, respectively, to cause plasma discharge,
wherein the first and second power sources are controlled to prevent pulse ON times of the modulated pulse voltages from coinciding with each other.

4. An electronic device production apparatus as set forth in claim 3, wherein the high frequency voltages each have a frequency in the range between a radio frequency and a ultra high frequency.

5. An electronic device production apparatus as set forth in claim 3, wherein the first and second power sources are capable of controlling the pulse ON times in the range between 1 μs and 100 μs, and pulse OFF times in the range between 5 μs and 500 μs.
